(19) United States
(12) Patent Application Publication
(10) Pub. No.: US 2019/0027527 A1
(43) Pub. Date: Jan. 24, 2019

(54) Avalanche photodiode detector array with a crosstalk reduction layer

(71) Applicants: Tomislav Suligoj, Zagreb (HR); Tihomir Knezevic, Zagreb (HR); Zeljko Osrecki, Zagreb (HR)

(72) Inventors: Tomislav Suligoj, Zagreb (HR); Tihomir Knezevic, Zagreb (HR); Zeljko Osrecki, Zagreb (HR)

(73) Assignee: University of Zagreb, Faculty of Electrical Engineering and Computing, Zagreb (HR)

(21) Appl. No.: 16/034,672

(22) Filed: Jul. 13, 2018

Related U.S. Application Data
(60) Provisional application No. 62/535,897, filed on Jul. 23, 2017.
(60) Provisional application No. 62/535,498, filed on Jul. 21, 2017.

(51) Int. Cl. H01L 27/146; H01L 31/107

(52) U.S. Cl. CPC H01L 27/14643; H01L 27/1463; H01L 31/107

(57) ABSTRACT

A photodiode detector array comprises: a substrate comprising a front surface and a mounting surface; a first active region and a second active region, each of said first and second active regions being operatively configured to detect electromagnetic radiation in a wavelength range, and each of said first and second active regions being formed within said substrate and disposed proximate to said front surface; and a layer formed within said substrate and disposed proximal to said mounting surface, wherein said layer exhibits an electromagnetic wave absorption coefficient greater than or equal to 3×10³ cm-1 in the wavelength range from 500 nm to 800 nm.

### FIELD

The invention pertains generally to image detectors used for recording phenomena in nature that emit very weak optical signals, and more specifically to indirect optical crosstalk reduction in single-photon avalanche diode (SPAD) arrays.

### BACKGROUND

Single-photon avalanche-diode arrays are optical imagers that can register processes in nature that emit very weak optical signals and they often also have the capability to precisely determine the arrival time of the photon. High-sensitivity two-dimensional arrays of photodetectors are required in many fields, the most demanding of them requiring single-photon sensitivity in the visible and near-infrared (400-850 nm), such as Fluorescence Lifetime Imaging (FLIM), micro-array-based biological analysis, confocal microscopy and adaptive optics.

Each pixel in the array consists of an active part, the SPAD, and readout electronics required to further process the signal. The SPAD is a pn-junction reverse biased above the breakdown voltage and thus operated in Geiger-mode, where each electron-hole pair can trigger an avalanche multiplication process. The avalanche current rises swiftly until quenched by an external circuit. The leading edge of the current pulse gives information about photon arrival time.

The fidelity of the SPAD output signal critically depends on the presence of noise. The most important source of noise in the output signal is unwanted carrier generation in the depletion region and optical crosstalk between the elements of the array. While the former is a property of the material, thus being the same for all the diodes in the array, the latter is a result of the light radiated from the avalanche multiplication process, which results in carrier recombination that causes photon emission and in turn false detections in adjacent diodes. Both phenomena are noise sources detected as a dark count rate (DCR). The optical crosstalk is both direct from the interaction between neighboring diodes and indirect from the light reflected from the backside of the substrate. Indirect optical crosstalk is pronounced in SPAD arrays with thin substrate where the substrate acts as a waveguide.

FIG. 1 is a cross-sectional view of a prior art detector array 10. The photodiode detector array 10 is a SPAD array with two pixels 14 and 16 (also referred to herein as “active regions”) in the displayed portion. Active regions 14 and 16 are processed on a silicon substrate 12 using standard semiconductor fabrication technology as is well known in the art. The detector array 10 includes a front surface 18 and a back surface 20. The photodetector array 10 may be mounted by attaching the back surface to a metal contact 22 in which case the light to be detected is incident from the front surface (shown in FIG. 1). The photodetector array 10 may also be mounted by attaching the front surface to a metal contact in which case the light to be detected is incident from the back surface of the substrate 12 (not shown in FIG. 1).

During normal operation of the SPAD array, the electrical bias on the SPAD pixels is larger than the nominal pn-junction breakdown voltage and the detection of photons is multiplied by impact ionization. A single charge carrier injected into a depletion region of active regions 14 or 16 triggers an avalanche breakdown which produces an avalanche current. During the avalanche breakdown process of the active regions 14 and 16, carriers gain a large amount of energy due to a high applied reverse voltage. A photodiode during an avalanche breakdown process emits a radiation (also referred to herein as “secondary photon emission”) with a peak intensity in the visible wavelength range. The secondary photon emission, radiated from the active region 14, propagates through silicon substrate 12 and reaches depletion region of the active device 16 (or vice versa). In the direct path 26, a photon is emitted by one active region and absorbed by the other, while in the indirect path 28 the photon emitted by secondary photon emission in active device 14 traverses the substrate 12 (shown with 28), reflects on the back surface of the chip 20, and returns to the active region 16 (also shown with 28), where it is absorbed creating a current pulse which appears as a detected light, but is in fact a false current pulse adding to the noise of the detector, thereby compromising the performance of the detector 10. The detection of secondary photon emission radiation by either the first active region 14 or by the second active region 16 is also referred to herein as “crosstalk”.

The secondary photon emission may escape active region 14 by two paths (same applies to the active region 16 as long as arrow directions shown in FIG. 1 are reversed). Path 26, referred to herein as direct path, is nearly parallel to the front surface 28, wherein radiation travelling said path has an exponentially decaying intensity with respect to the distance between the active regions 14 and 16. A second path 28, referred to herein as indirect path, that a secondary photon emission may take between active region 14 and active region 16 is via a reflection at the back surface 20. The indirect path 28 is becoming significant for thin SPAD arrays, where the thickness of the substrate 12 can be as small as a few tens of microns.

There is a need in industry for a detector array with improved noise performance that can be fabricated in standard semiconductor manufacturing technology. This patent application discloses such a solution.

### Overview

This disclosure describes SPAD arrays in which the indirect optical crosstalk path is reduced, while at the same time allowing electrical connection to the substrate of the detector array.

A photodiode detector array configured to facilitate a reduction in indirect optical crosstalk is provided. The photodiode detector array includes a first active region and a second active region for detecting photons. The photodiode detector array includes a layer that is used to reduce the indirect optical crosstalk and to secure an electrical connection to the substrate.

### SUMMARY

Embodiments generally relate to methods and apparatus for improved photodiode detector arrays. In one embodiment, a photodiode detector array comprises: a substrate comprising a front surface and a mounting surface; a first active region and a second active region, each of said first and second active regions being operatively configured to detect electromagnetic radiation in a wavelength range, and each of said first and second active regions being formed within said substrate and disposed proximate to said front surface; and a layer formed within said substrate and disposed proximal to said mounting surface, wherein said layer exhibits an electromagnetic wave absorption coefficient greater than or equal to 3×10³ cm⁻¹ in the wavelength range from 500 nm to 800 nm. In another embodiment, a photodiode detector array comprises: a substrate comprising a front surface, a mounting surface opposite said front surface, and a first material extending between said front surface and said mounting surface; a first active region and a second active region, each of said first and second active regions being operatively configured to detect electromagnetic radiation in a wavelength range, and each of said first and second active regions being formed within said substrate and disposed proximate to said front surface; and a layer comprising a second material, said layer overlying said mounting surface, exterior to said substrate, wherein said layer exhibits an electromagnetic wave absorption coefficient greater than or equal to 3×10³ cm-1 in the wavelength range from 500 nm to 800 nm.

### BRIEF DESCRIPTION OF THE DRAWINGS

FIG. 1 (PRIOR ART) is a cross-sectional view of an exemplary photodiode detector array with two pixels;

FIG. 2 shows the intensity of the secondary photon emission radiation in the wavelength range from 500 nm to 800 nm;

FIG. 3 shows an electromagnetic wave absorption coefficient for a highly doped silicon, amorphous boron and amorphous silicon;

FIG. 4 is a cross-sectional view of an exemplary photodiode detector array with two pixels further comprising an indirect optical crosstalk reduction layer and an isolation region for direct crosstalk elimination;

FIG. 5 shows an indirect optical crosstalk for the array with 3×10²⁰ cm⁻³ B-doped layer;

FIG. 6 is a magnified cross-sectional view of an exemplary photodiode detector array with a crosstalk reduction layer implemented as a multiplicity of layers of a-B and a-Si;

FIG. 7 shows an indirect optical crosstalk for the array with a layer implemented as a multiplicity of layers of a-B and a-Si; and

FIG. 8 compares an indirect optical crosstalk for an array with layer being implemented as As-doped Si, B-doped Si and multiplicity of layers of a-B and a-Si.

### DETAILED DESCRIPTION OF EMBODIMENTS

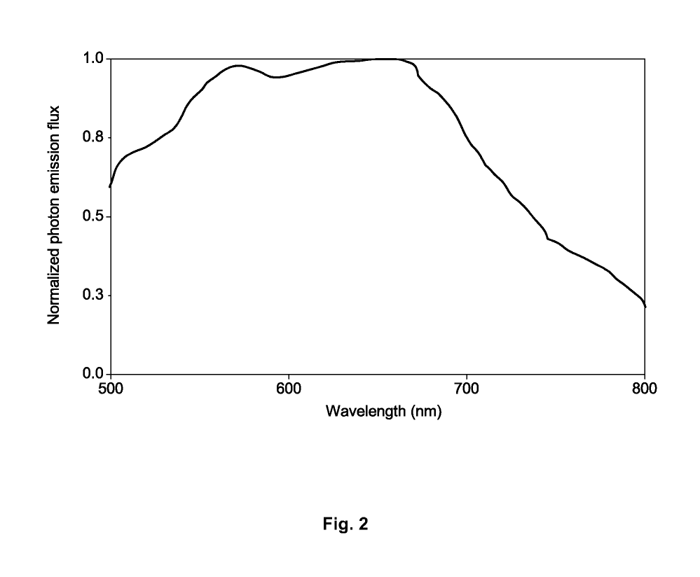

In one embodiment of present invention, a low-noise SPAD array is mounted substrate down and exhibits reduced reflection from the mounting surface of the substrate, thereby reducing absorption of secondary photon emission. FIG. 2 shows a normalized photon emission flux of secondary photon emission from a silicon avalanche region as a function of wavelength in the wavelength range from 500 nm to 800 nm. The photon flux is normalized to the maximum value at the wavelength of 650 nm. A photon with a wavelength of around 650 nm can generate carriers in the active regions of the array, as they are also made out of silicon, causing false detections. Also, a radiation in said wavelength range can generate carriers in the substrate increasing false detections solely due to a diffusion of carriers from the substrate to the active regions. Mounting the detector array substrate down allows one to use a metal contact attached to the mounting surface of the substrate to sink generated carriers and prevent diffusion toward the active regions.

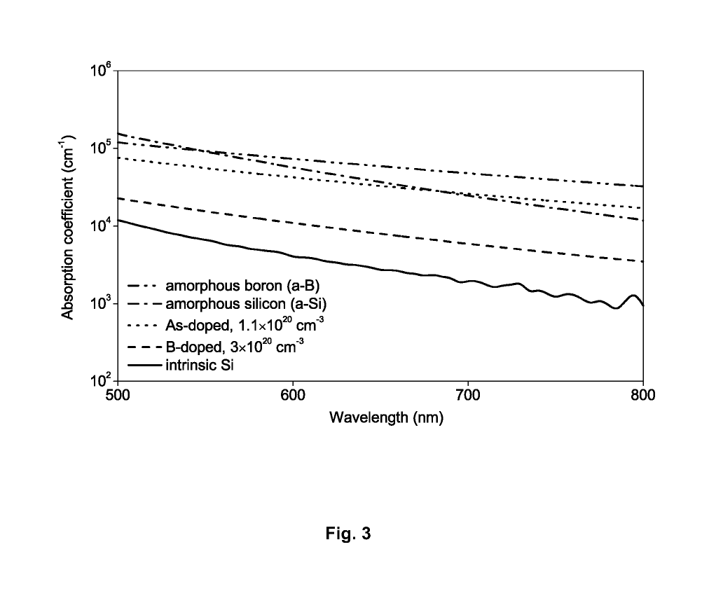

FIG. 3 is a plot of an electromagnetic wave absorption coefficient (also referred to herein as “absorption coefficient”) for silicon (Si) doped with arsenic (As) (1.1×10²⁰ cm⁻³), silicon doped with boron (B) (3×10²⁰ cm⁻³), amorphous boron (a-B) and amorphous silicon (a-Si) as a function of wavelength in the wavelength range from 500 nm to 800 nm. Said materials can be used in certain array embodiments to increase the secondary photon emission radiation absorption. Furthermore, As-doped Si and B-doped Si can be realized using ion implantation, a well known method for creating regions of doped semiconductor which is compatible with standard semiconductor fabrication. In such a way, the thickness and doping concentration of the doped layers can be very well controlled. By increasing the doping concentration, the absorption coefficient is increasing, therefore, indirect optical crosstalk is decreasing.

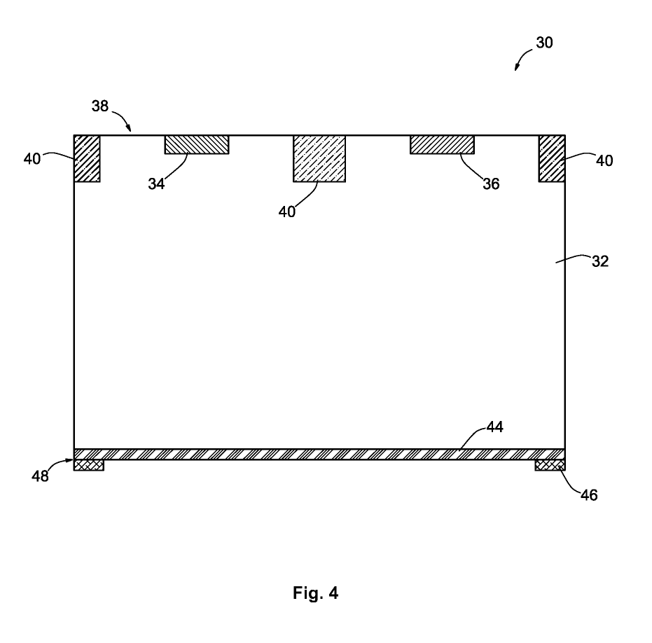

FIG. 4 discloses a cross-sectional view of a non-limiting exemplary detector array 30 with active regions 34 and 36, and isolation region 40, formed in substrate 32. Substrate 32 has a front surface 38 (shown at the top of this figure) and a mounting surface 48 (shown at the bottom of this figure. Substrate 32 is connected to metal contact 46 through mounting surface 48. Isolation region 40, processed using standard semiconductor fabrication technology, comprises trenches that block the direct optical path between active regions 34 and 36. In one embodiment, the trenches are filled with aluminum or platinum.

Indirect optical crosstalk reduction is accomplished by using layer 44 that is configured to attenuate radiation travelling along an indirect path from one active region to the other (from 34 to 36 or vice versa, via mounting surface 48) while enabling an electrical contact at mounting surface 48 to function as desired. In one embodiment, substrate 32 is n-type Si with a doping concentration of 10¹⁵ cm⁻³ and layer 44 is a region of that substrate with an increased As doping concentration of 1.1×10²⁰ cm⁻³, the region being positioned proximate to mounting surface 48. As-doped silicon has a large absorption coefficient in the visible wavelength range, therefore, it is suitable for use as a photon absorbing material for indirect crosstalk reduction.

In the wavelength range from 500 nm to 800 nm, a layer with As concentration of 1.1×10²⁰ cm⁻³ has a minimum absorption coefficient of around 1.7×10⁴ cm⁻¹ (at 800 nm), which is almost 20 times greater than the absorption coefficient of the substrate 32 (As-doped, 10¹⁵ cm⁻³). Also, said layer has a low electrical resistivity of 7×10⁻⁴ Ωcm thus providing good contact to substrate 32.

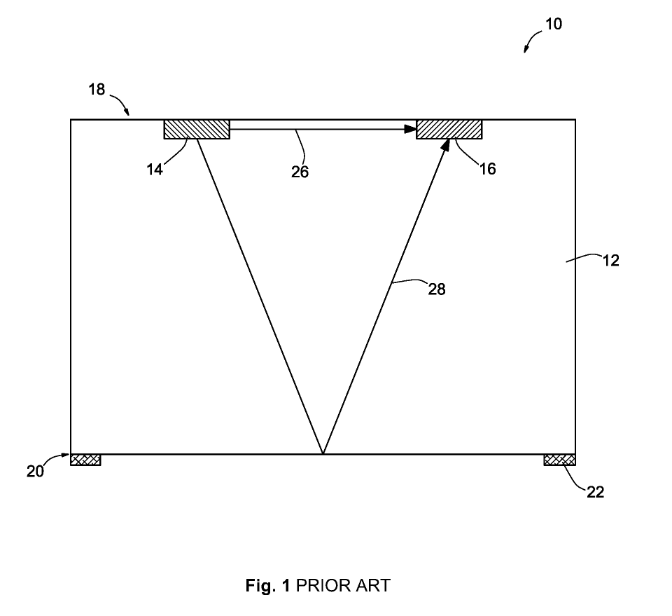

In an alternative embodiment, wherein substrate 32 is made of a p-type Si, layer 44 is implemented as a heavily doped p-type region exhibiting large absorption coefficient and low electrical resistivity. In the wavelength range from 500 nm to 800 nm, a layer with boron (B) doping concentration of 3×10²⁰ cm⁻³ has a minimum absorption coefficient of around 3×10³ cm⁻¹ (at 800 nm), which is more than 3 times greater than the absorption coefficient of the substrate 32 (B-doped, 10¹⁵ cm⁻³). Also, said layer has a low electrical resistivity of 3.9×10⁻⁴ Ωcm thus providing a way to contact the substrate 32. The attenuation of an indirect path (such as path 28 shown in FIG. 1) is greater for larger thickness of the layer 44. Because ion implantation of boron is by now a mainstream process in semiconductor fabrication technology, it is possible to fabricate heavily doped layers of boron with a thickness of up to few tens of micrometers. In this way, a somewhat smaller absorption coefficient of the B-doped layer can be compensated with a greater thickness of the layer 44.

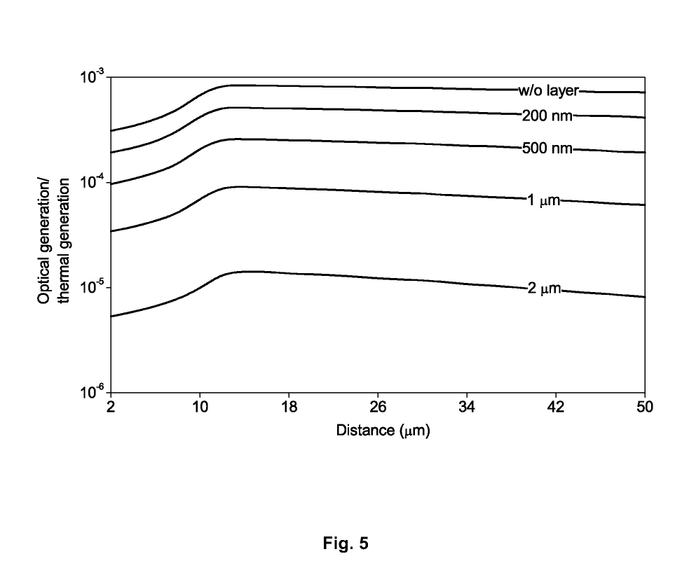

FIG. 5 shows simulation results for normalized optical generation in the second active region due to a secondary photon emission in the first active region, as a function of distance, for layer 44 implemented as a 3×10²⁰ cm⁻³ B-doped Si. The optical generation is normalized to a Shockley-Read-Hall generation in the second active region. The total reflection from the mounting surface takes place for the distance between the active regions of more than approximately 12 μm for the 50 μm thick p-type Si substrate. With a 2-μm-thick B-doped layer, indirect optical crosstalk can be reduced by 2 orders of magnitude.

In another embodiment, instead of the indirect crosstalk blocking layer being formed in the substrate, it can be fabricated by deposition of amorphous Si (a-Si) and/or amorphous B (a-B) over the mounting surface of the substrate, so that the deposited material or materials lie between the substrate and external contacts. Said materials are compatible with a p-type substrate 32 and have greater absorption coefficients than (non-amorphous) B-doped layers. In the wavelength range from 500 nm to 800 nm, layers of deposited a-B and a-Si have a minimum absorption coefficient of around 3.4×10⁴ cm⁻¹ and 1.1×10⁴ cm⁻¹, respectively (at 800 nm). Thick layers of a-B can be a fabrication challenge, because of that, multiplicity of layers of a-B and a-Si can be used to suppress indirect optical path. Because of large absorption coefficients of both a-B and a-Si, the multiplicity of layers of a-B and a-Si is utilized to circumvent the difficulty of growing very thick layers of a-B.

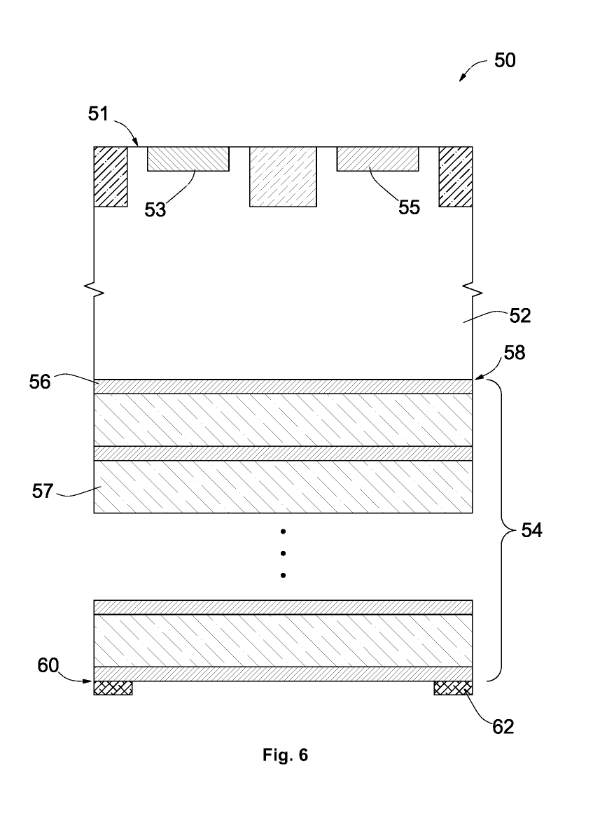

FIG. 6 is a cross-sectional view of an exemplary detector array 50 utilizing a multiplicity of deposited layers of a-B and a-Si as a crosstalk reduction layer 54. Active regions 53 and 55 are shown, formed into front surface 51 of substrate 52. Layer 54 is positioned on mounting surface 58 of substrate 52, extending downwards and away, relative to the bulk of the device, in the device orientation shown in the figure. Layer 58 comprises several a-B 56 and a-Si 57 layers, wherein larger number of layers in the multiplicity of layers of a-B and a-Si facilitates a greater overall absorption coefficient. Metal contacts 62 are present on the outermost external surface 60 of layer 58. Although a somewhat expensive solution, this exemplary embodiment can be used for capturing noise-free images in very demanding applications, such as Fluorescence Lifetime Imaging (FLIM).

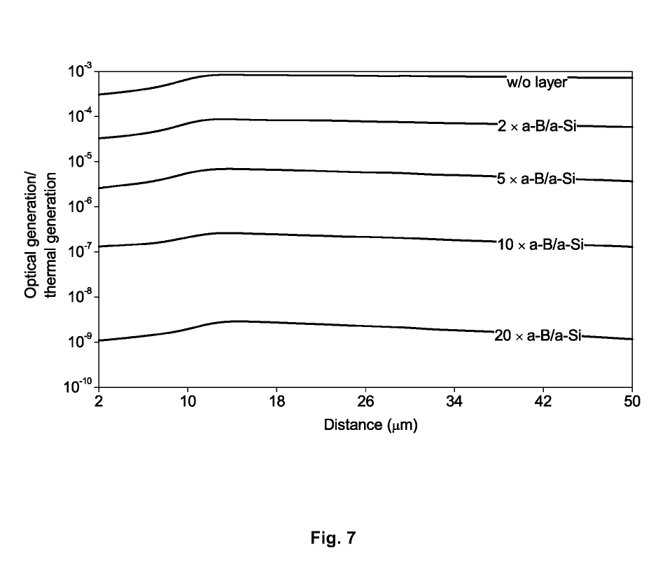

FIG. 7 shows simulation results for normalized optical generation in the second active region due to a secondary photon emission in the first active region as a function of distance, for the composite layer implemented as a multiplicity of layers of a-B and a-Si. With a multiplicity of layers of a-B and a-Si made of 20 a-B/a-Si deposited layers, 6 orders of magnitude crosstalk reduction is achieved. Even for 5 a-B/a-Si layers in the multiplicity of layers of a-B and a-Si, with the overall thickness of 500 nm, a greater crosstalk reduction is achieved compared to a 2-μm-thick B-doped layer (FIG. 5).

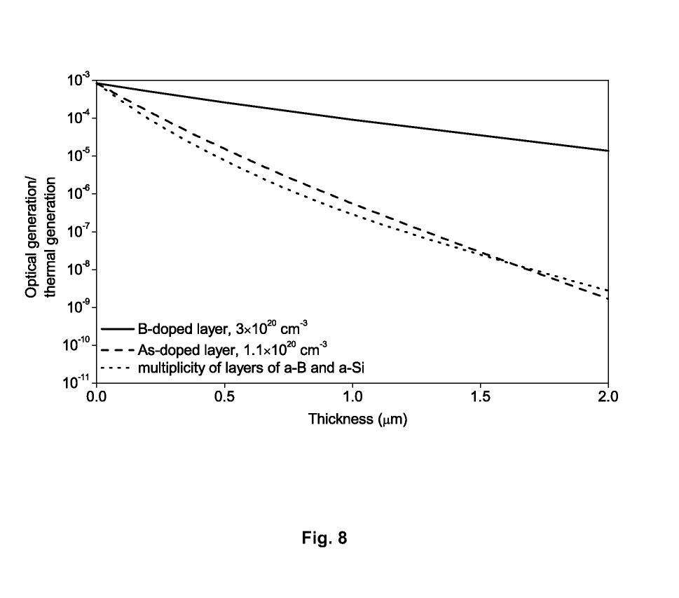

FIG. 8 shows simulation results for normalized optical generation in the second active region due to a secondary photon emission in the first active region while varying the thickness of the crosstalk reduction layer. Results for all three embodiments are shown, wherein it is seen that the best performance is achieved with the layer implemented as a multiplicity of layers of a-B and a-Si. On the other hand, thick layers of B-doped Si and As-doped Si are less complex to process, therefore, their increased thickness can compensate for a lower absorption coefficient.

Although the description has been described with respect to particular embodiments thereof, these particular embodiments are merely illustrative, and not restrictive.

Embodiments described herein provide various benefits to applications requiring high performance photodetectors. In particular, embodiments are directed towards providing photodiode detector arrays with significant reductions in both direct and indirect optical crosstalk, hence providing low noise photodetection.

1. A photodiode detector array comprising:
a substrate comprising a front surface and a mounting surface;
a first active region and a second active region, each of said first and second active regions being operatively configured to detect electromagnetic radiation in a wavelength range, and each of said first and second active regions being formed within said substrate and disposed proximate to said front surface; and
a layer formed within said substrate and disposed proximal to said mounting surface, wherein said layer exhibits an electromagnetic wave absorption coefficient greater than or equal to 3×10³ cm⁻¹ in the wavelength range from 500 nm to 800 nm.

2. The photodiode detector array of claim 1, wherein said mounting surface is attached to a metal contact.

3. The photodiode detector array of claim 2, further comprising an isolation region positioned between said first active region and said second active region, wherein said isolation region exhibits an electromagnetic wave absorption coefficient greater than or equal to 3×10³ cm⁻¹ in the wavelength range from 500 nm to 800 nm.

4. The photodiode detector array of claim 3, wherein said layer exhibits an electrical resistivity less than 7×10⁻³ Ωcm.

5. A photodiode detector array comprising:
a substrate comprising:
a front surface;
a mounting surface opposite said front surface; and
a first material extending between said front surface and said mounting surface;
a first active region and a second active region, each of said first and second active regions being operatively configured to detect electromagnetic radiation in a wavelength range, and each of said first and second active regions being formed within said substrate and disposed proximate to said front surface; and
a layer comprising a second material, said layer overlying said mounting surface, exterior to said substrate, wherein said layer exhibits an electromagnetic wave absorption coefficient greater than or equal to 3×10³ cm⁻¹ in the wavelength range from 500 nm to 800 nm.

6. The photodiode detector array of claim 5, wherein said layer is attached to a metal contact.

7. The photodiode detector array of claim 6, further comprising an isolation region positioned between said first active region and said second active region, wherein said isolation region exhibits an electromagnetic wave absorption coefficient greater than or equal to 3×10³ cm⁻¹ in the wavelength range from 500 nm to 800 nm.

8. The photodiode detector array of claim 7, wherein said second material is selected from the group consisting of: amorphous silicon, amorphous boron and polycrystalline silicon.

9. The photodiode detector array of claim 7, wherein said layer comprises a multiplicity of layers of amorphous boron and amorphous silicon.
